(19) United States
(12) Patent Application Publication
(10) Pub. No.: US 2026/0259110 A1
(43) Pub. Date: Sep. 3, 2026

(54) Device and method for processing a digital signal

(71) Applicant: Aktiebolaget SKF, Goteborg (SE)

(72) Inventors: James P. LEBLANC, Lulea (SE); Robert OLLSON, Norrkoping (SE)

(21) Appl. No.: 19/547,882

(22) Filed: Feb. 24, 2026

(30) Foreign Application Priority Data
Mar. 3, 2025 (DE) 102025107941.2

(51) Int. Cl. G01M 13/045; G01R 23/16

(52) U.S. Cl. CPC G01M 13/045; G01R 23/16

(57) ABSTRACT

A device (10) for processing a digital signal. The device (10) includes a segmenting means (15), a spectral analysis means (16, 16a, 16b), a first determining means (17), a second determining means (20), a third determining means (21), a Farrow structure (18), an implementing means (24), a fourth determining means (22), and a fifth determining means (23). The device performs machine-health assessment for systems and/or sensors which have no means for direct rotational speed measurement.

### CROSS-REFERENCE TO RELATED APPLICATION

This application claims priority to German Patent Application No. 102025107941.2, filed Mar. 3, 2025, the entirety of which is hereby incorporated by reference.

### FIELD

The present disclosure is directed to devices for processing a digital signal and methods for processing a digital signal.

### BACKGROUND

Condition monitoring algorithms, for example to detect a fault of a bearing such as a fault of an inner raceway of the bearing, require a constant rotational speed of the bearing to work properly.

Generally, condition monitoring algorithms perform spectral analysis of the rotating bearing to detect faults from specific tones and harmonics.

Rotational speed changes of the bearing during signal measurement smears out the spectral tones reducing the ability to identify the frequencies and harmonics that may be associated with faults, for example faults of an inner raceway of the bearing or faults of the outer raceway of the bearing.

Without access to tachometer or other direct speed measurement devices, the difficulties to correct for speed variations may be further exacerbated by complex speed variation profiles such as profiles containing several accelerations, deceleration phases, as well as time-varying tone amplitude change.

Consequently, the present disclosure intends to correct deleterious effects of rotational speed changes.

### SUMMARY

According to an aspect a method for processing a continuous signal sampled at a fixed sample rate, the continuous signal being representative of the operation of a rotating element, the rotating element undergoing rotational speed changes is proposed.

The method comprises:
segmenting the sequential timestamped samples of the digital signal into a plurality of frames and clustering the plurality of frames in a plurality of pairs of frames, each pair of frames comprising a first frame and a second frame so that samples of the second frame are sampled after the samples of the first frame,
for each pair of frames:
(a) performing a spectral analysis of the first frame to determine a first vector comprising frequency bins below or equal to the Nyquist frequency of the sampling of the continuous signal,
(b) performing a spectral analysis of the second frame to determine a second vector comprising frequency bins below or equal to the Nyquist frequency of the sampling of the continuous signal,
(c) determining a first intermediary unit vector comprising the absolute value of at least one frequency bin of the first vector and a second intermediary vector comprising the absolute value of at least one frequency bin of the second vector,
(d) determining a first array of speed change coefficients, each speed change coefficient being representative of an expected speed change of the rotating element,
(e) determining a first initial value from the first array of speed change coefficients,
(f) resampling the frequency bins of the second intermediary vector by a Farrow structure controlled by a first control variable from an original unit index increment representative of the sampling increment of the continuous signal at the fixed sample rate to a first index increment, the second intermediary vector resampled at the first index increment and normalized being a first resulting unit vector, and resampling the frequency bins of the second intermediary vector by the Farrow structure controlled by a second control variable from the original unit index to a second index increment, the second intermediary vector resampled at the second index increment and normalized being a second resulting unit vector, the first and second control variable being determined by an iterative line search method to converge the difference between a first inner product value and a second inner product value toward zero, the initial conditions of the iterative line search method comprising at least the first initial value and a second initial value bigger than the first initial value, the first inner product value being determined from the inner product of the first intermediary unit vector and the first resulting unit vector, and the second inner product value being determined from the inner product of the first intermediary unit vector and the second resulting unit vector,
(g) determining a result value when the difference between the first inner product value and the second inner product value is smaller than a predetermined threshold or the number of iterations of the iterative line search method is equal to a predetermined number of iterations, the result value being equal to the means of the first and second control variables, and storing the result value in a result array and a timestamp value determined from the sequential samples of the said pair of frames,
when the result value of each pair of the plurality of pairs of frames is stored in the result array, determining a correction profile from the result values and timestamp values stored in the result array, and
resampling the sequential timestamped samples of the continuous signal by the Farrow structure controlled by a third control variable, the third control variable following the correction profile, and
delivering the resampled sequential timestamped samples of the continuous signal.

The method allows machine-health assessment for systems and/or sensors which have no means for direct rotational speed measurement.

The method allows to use of any existing algorithm that has been designed for constant speed conditions and are industrially accepted, trusted and well-understood.

The method further obviates repetitive attempts at data acquisition that only must be discarded due to speed changes.

Instead, such data may now be used effectively. The suppression of repetitive attempts at data acquisition permit to save supply power of a system implementing the method, for example a wireless system comprising a supply source such as a battery.

Preferably, determining the first initial value comprises for each speed change coefficient of the first array:
setting the first control variable to the value of the said speed change coefficient,
resampling the frequency bins of the second intermediary vector by the Farrow structure controlled by the first control variable from an original unit index increment representative of the sampling of the continuous signal at the fixed sample rate to a first index increment, the second intermediary vector resampled at the first index increment and normalized being a first unit vector,
determining the inner product value of the first intermediary vector and the first unit vector, and storing the inner product value and the first control variable value in a second array, and
determining the greatest inner product value of the plurality of inner product values stored in the second array and the associated first control variable value, the associated first control variable value being the first initial value.

Advantageously, determining the correction profile comprises:
for each result value, determining a result timestamp value from the timestamp values associated to the said result value,
obtaining arrays of the result values depending on their result timestamp values, and
applying an interpolation to the result values to obtain the correction profile.

Preferably, the iterative line search method comprises a golden section line search.

Advantageously, the iterative line search method comprises a parabolic approximation line search, the initial conditions of the iterative line search method further comprising a third initial value equal to the means value of the first and second initial values.

Preferably, the method further comprising zero padding of at least the first and second frames before performing the spectral analysis.

According to another aspect, a device for processing a digital signal comprising sequential samples of a continuous signal sampled at a fixed sample rate is proposed.

The continuous signal is representative of the operation of a rotating element, the rotating element undergoing rotational speed changes.

The device comprises:
segmenting means configured to segment the sequential timestamped samples of the digital signal into a plurality of frames and to cluster the plurality of frames in a plurality of pairs of frames, each pair of frames comprising a first frame and a second frame so that samples of the second frame are sampled after the samples of the first frame,
spectral analysis means configured to perform a spectral analysis of the first frame to determine a first vector comprising frequency bins below or equal to the Nyquist frequency of the sampling of the continuous signal and a spectral analysis of the second frame to determine a second vector comprising frequency bins below or equal to the Nyquist frequency of the sampling of the continuous signal,
first determining means configured to determine a first intermediary unit vector comprising the absolute value of at least one frequency bin of the first vector and a second intermediary vector comprising the absolute value of at least one frequency bin of the second vector,
second determining means configured to determining a first array of speed change coefficients, each speed change coefficient being representative of an expected speed change of the rotating element,
third determining means configured to determine a first initial value from the first array of speed change coefficients,
a Farrow structure configured to:
be controlled by a first control variable to resample the frequency bins of the second intermediary vector from an original unit index increment representation of the sampling increment of the continuous signal at the fixed sample rate to a first index, the second intermediary vector resampled at the first index increment and normalized being a first resulting unit vector,
be controlled by a second control variable to resample the frequency bins of the second intermediary vector from the original unit index to a second index increment, the second intermediary vector resampled at the second index increment and normalized being a second resulting unit vector, and
be controlled by a third control variable to resample the sequential timestamped samples of the continuous signal, the third control variable following a correction profile,
implementing means configured to implement an iterative line search method to determine the first and second control variable by converging the difference between a first inner product value and a second inner product value toward zero, the initial conditions of the iterative line search method comprising at least the first initial value and a second initial value bigger than the first initial value, the first inner product value being determined from the inner product of the first intermediary unit vector and the first resulting unit vector, and the second inner product value being determined from the inner product of the first intermediary unit vector and the second resulting unit vector,
fourth determining means configured to determine a result value when the difference between the first inner product value and the second inner product value is smaller than a predetermined threshold or the number of iterations of the iterative line search method is equal to a predetermined number of iterations, the result value being equal to the means of the first and second control variables, and configured to store the result value in a result array and a timestamp value determined from the sequential samples of the said pair of frames,
fifth determining means configured to determine the correction profile from the result values and timestamp values stored in the result array when the result value of each pair of the plurality of pairs of frames is stored in the result array.

According to another aspect, a bearing device is proposed.

The bearing device comprises:
a bearing provided with an inner ring and with an outer ring capable of rotating concentrically relative to one another,
a sensor configured to measure the vibrations of the said inner or outer ring and configured to deliver a continuous signal
a sampler configured to sample the continuous signal at a fixed sample rate and configured to deliver the digital signal comprising the sequential samples, and
a device as defined above configured to process the digital signal.

### BRIEF DESCRIPTION OF THE DRAWINGS

Other advantages and features of the present disclosure will appear on examination of the detailed description of embodiments, in no way restrictive, and the appended drawings in which:

FIG. 1 illustrates schematically a machine according to the present disclosure;

FIG. 2 illustrates schematically an example of a device for processing a digital signal according to the present disclosure;

FIG. 3 illustrates schematically an example of a Farrow structure;

FIG. 4 illustrates schematically a method to determine the coefficients of the Farrow structure;

FIG. 5 illustrates schematically a method for processing a digital signal according to the present disclosure;

FIG. 6 illustrates schematically an example of a correction profile according to the present disclosure; and

FIGS. 7 and 8 illustrate examples of spectrum delivered by spectral analysis means for a bearing undergoing rotational speed changes during measurement according to the prior art and according to the present disclosure.

### DETAILED DESCRIPTION

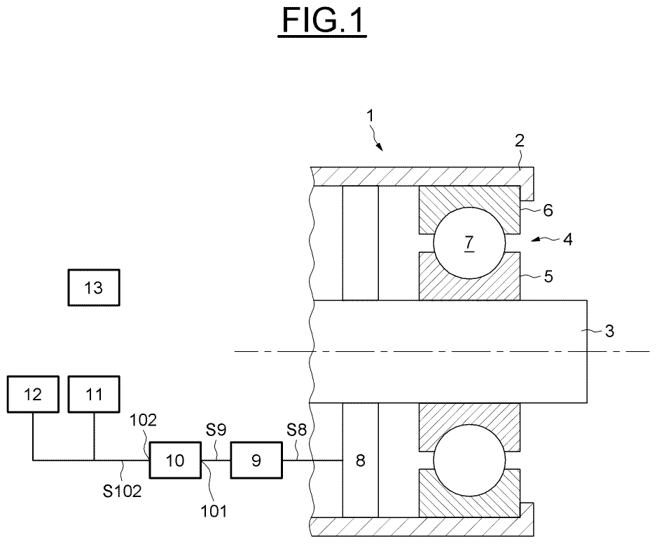

Reference is made to FIG. 1 which represents schematically a partial longitudinal cross section of a machine 1.

The machine 1 comprises a housing 2 and a shaft 3 supported in the housing 2 by a rolling bearing 4 (e.g. roller bearing or ball bearing).

The rolling bearing 4 is provided with an inner ring 5 mounted on the shaft 3, and with an outer ring 6 mounted into the bore of the housing 2. The outer ring 6 radially surrounds the inner ring 5. The inner and outer rings 5, 6 rotate concentrically relative to one another.

The rolling bearing 4 is further provided with a row of rolling elements 7 radially interposed between inner and outer raceways of the inner and outer rings 5, 6. In the illustrated example, the rolling elements 7 are balls. Alternatively, the rolling bearing may comprise other types of rolling elements 7, for example rollers. In the illustrated example, the rolling bearing comprise one row of rolling elements 7. Alternatively, the rolling bearing comprise may comprise several rows of rolling elements.

A sensor 8 is mounted in the housing 2 to measure vibrations of the bearing 4 undergoing rotational speed changes.

The sensor 8 may be mounted on a bore of the housing 2.

In variant, the sensor 8 may be mounted elsewhere on the machine, near the outer ring 6 or in the vicinity of housing 2, for example.

The sensor 8 delivers a continuous signal S8 representative of the operation of a rotating element.

The rotating element may be the bearing 4 and the sensor 8 delivers the continuous signal S8 representative of the vibration of the bearing 4 to an input of a sampler 9.

The sampler 9 delivers a digital signal S9 comprising sequential timestamped samples xₚ of the continuous signal S8 sampled at a fixed sample rate to an input 101 of a device 10 for processing the digital signal S9, p being an integer.

The bearing 4, the sensor 8, the sampler 9 and the device 10 form a bearing device.

A memory (not represented) may store the output signal S9 and delivers the output signal S9 to the device 10.

An output 102 of the device 10 may be connected to implementing means 11 implementing at least one constant speed time domain algorithm from a first output signal S102 delivered by the device 10 on the first output 102, for example to implement an enveloping fault detection algorithm.

The output 102 of the device 10 may be further connected to second implementing means 12 to perform a spectral analysis of the output of the device 10.

The second implementing means 12 implement for example a fast Fourier transform.

The first and second implementing means 11, 12 are for example each made of a processing unit implementing the said algorithm.

A processing unit 13 implements the sensor 8, the sampler 9, and the device 10.

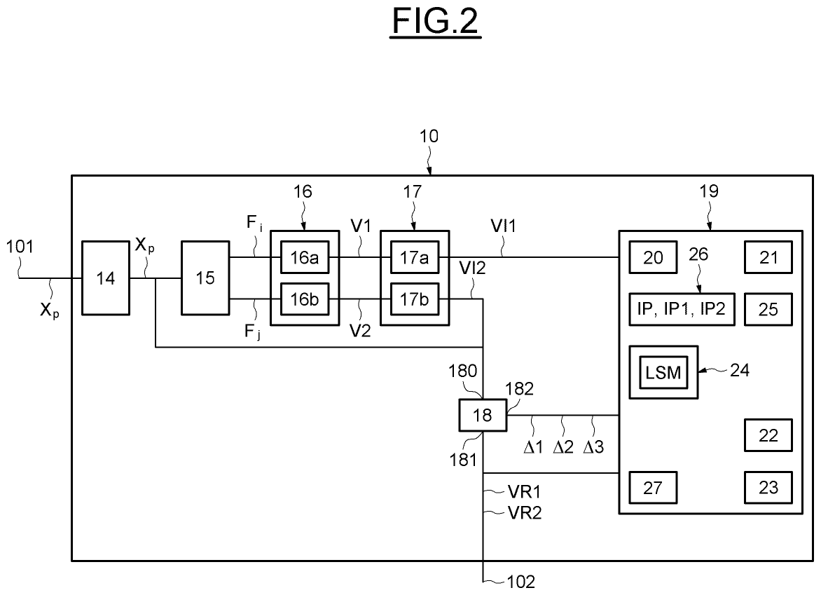

FIG. 2 illustrates schematically an example of the device 10.

The device 10 comprises a first memory 14, segmenting means 15, spectral analysis means 16, first determining means 17, a Farrow structure 18 and a controlling module 19.

The first memory 14 is intended to store the digital signal S9 comprising the sequential samples xₚ received on the input 101 of the device 10.

The first memory 14 is connected to an input of the segmenting means 15 and an input 180 of the Farrow structure 18.

The segmenting means 15 further comprise a first output connected to an input of a first spectral analysis module 16a of the spectral analysis means 16 and a second output connected to an input of a second spectral analysis module 16b of the spectral analysis means 16.

The segmenting means 15 are intended to segment the sequential timestamped samples xₚ of the digital signal into a plurality of frames F1, F2 . . . . Fₖ₋₁, Fₖ being an integer so that k varying between 1 and the integer P. The frames have an identical size.

The integer P is determined according to the resolution expected to capture speed changes of the machine in each frame.

The segmenting means 15 are further intended to cluster the plurality of frames in a plurality of pairs of frames.

Each pair of frames comprises a first frame Fi and a second frame Fj, i, j being two different integers between 1 and P.

The segmenting means 15 are intended to deliver the first frame Fi on the input of the first spectral analysis module 16a and the second frame Fj on the input of the second spectral analysis module 16b.

An output of the first spectral analysis module 16a is connected to an input of a first module 17a of the first determining means 17 and an output of the second spectral analysis module 16b is connected to an input of a second module 17b of the first determining means 17.

The first spectral analysis module 16a is intended to perform a spectral analysis of the first frame Fi to determine a first vector V1 comprising frequency bins below or equal to the Nyquist frequency of the sampling of the continuous signal S8 and to deliver the first vector V1 to the input of the first module 17a of the first determining means 17. The zero padding of the first and second frames Fi, Fj improves the spectral resampling.

The second spectral analysis module 16b is intended to perform a spectral analysis of the second frame Fj to determine a second vector V2 comprising frequency bins below or equal to the Nyquist frequency of the sampling of the continuous signal S8 and to deliver the second vector V2 to the input of the second module 17b of the first determining means 17.

An output of the first module 17a of the first determining means 17 is connected to a first input of the controlling module 19.

An output of the second module 17b of the first determining means 17 is connected to the input 180 of the Farrow structure 18.

The first module 17a of the first determining means 17 is intended to determine a first intermediary unit vector VI1 and to deliver the first intermediary unit vector VI1 on the output of the said module.

The second module 17b of the first determining means 17 is intended to determine a second intermediary vector VI2 and to the deliver the second intermediary vector VI2 on the output of the said module.

The first module 17a is intended to determine the absolute value of each frequency bin of the first vector V1 and to determine the first intermediary unit vector VI1 comprising the absolute value of at least one frequency bin of the first vector V1.

The second module 17b is intended to determine the absolute value of each frequency bin of the second vector V2 and to determine the second intermediary vector VI2 comprising the absolute value of at least one frequency bin of the second vector V2.

The first intermediary unit vector VI1 comprise the absolute value of at least one frequency bin of the first vector V1 and the second intermediary vector VI2 may comprise the absolute value of at least one frequency bin of the second vector V2 so that no complex numbers are input to the Farrow structure 18.

The first and second modules 17a, 17b may mask out frequency bin(s) of the first vector V1 and second vector V2 associated to disturbance frequencies, for example interference frequencies of power line noise so that the first intermediary unit vector VI1 and the second intermediary vector VI2 do not comprise the disturbance frequencies.

The Farrow structure 18 further comprises an output 181 connected to the controlling module 22 and the output 102 of the device 10.

The Farrow structure 18 further comprises a connection 182 connected to the controlling module 19.

The controlling module 22 comprises second determining means 20, third determining means 21, fourth determining means 22, fifth determining means 23 and implementing means 24.

The controlling module 22 further comprises a counter 25, computation means 26 and a memory 27.

The implementing means 24 are intended to an iterative line search method LSM.

Farrow structures are known from the document U.S. Pat. No. 4,866,647.

The Farrow structure 18 is explained in the following.

The Farrow structure 18 iteratively adjusts intersample delays (resampling) of measurement data.

From the desired inter sample increments Δ or control variable, the corresponding resampled indices at are deconstructed into integer values ρᵢ and fractional values μᵢ.

Integer values ρᵢ correspond to indices of the input vector and fractional values μᵢ are implemented by the Farrow structure 18.

The Farrow structure 18 is based on a N order finite impulse response FIR filter with coefficients h(n, μ) that may be varied by means of a control variable μ equal to the inter-sample position or delay of the Farrow structure, n being an integer between 0 and N.

The filter coefficients h1(n, μ) are formed from a polynomial of the control variable μ.

The coefficient h1(n, μ) is equal to:

$$h 1 ( n , μ ) = {\sum }_{m = 0}^{M} {C}_{mn} {μ}^{m} \qquad ( 1 )$$

where M is the order of a set of polynomials whose value is chosen by performance needs. The matrix C represents the collection of each coefficient Cₘₙ of each M-order polynomial for each filter coefficient h1(n, μ). Each Cₘₙ coefficient implements the (n+1)-tap filter implementing a delay of u denoted as h1(n, μ).

The coefficients Cₘₙ may be represented as a coefficient matrix C of dimension (M+1)×(N+1).

$$C = [ \begin{matrix}{C}_{00} & ⋯ & {C}_{ON} \\ ⋮ & ⋱ & ⋮ \\ {C}_{M 0} & ⋯ & {C}_{MN}\end{matrix} ] \qquad ( 2 )$$

The transfer function H(z, μ) of the Farrow structure 18 is given by:

$$H ( z , μ ) = {\sum }_{m = 0}^{M} {C}_{m} ( z ) \cdot {μ}^{m} \qquad ( 3 )$$

$$with$$

$${C}_{m} ( z ) = {\sum }_{n = 0}^{N} {C}_{mn} \cdot {z}^{- n} \qquad ( 4 )$$

for m varying between 0 and M, and n varying from 0 and N.

The term Cₘ(z) refers to a subfilter of the Farrow structure 18, the Farrow structure 18 comprising M+1 subfilters.

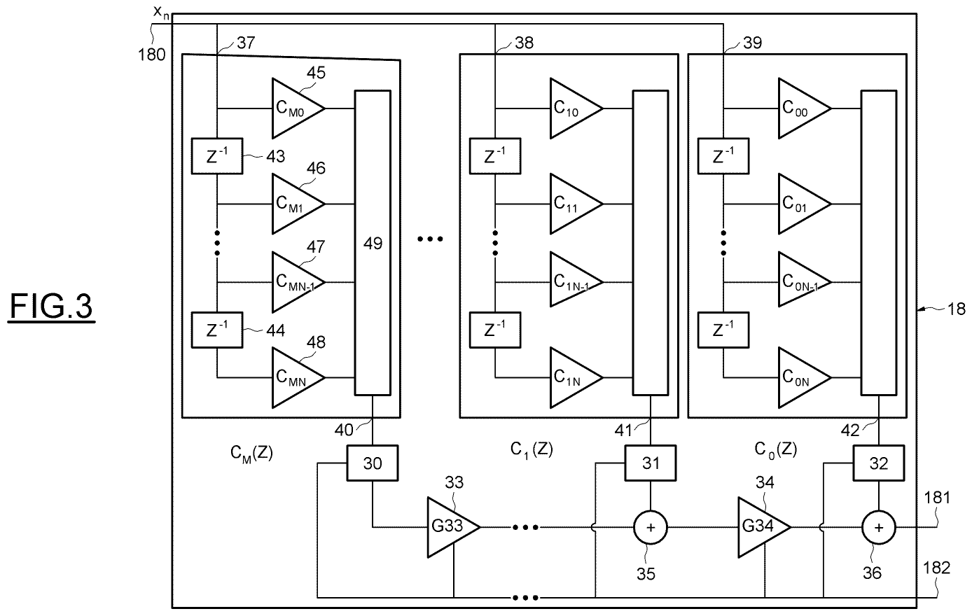

FIG. 3 illustrates schematically an example of the Farrow structure 18.

The Farrow structure 18 comprises M+1 subfilters denoted C_{M}(z), . . . , C₁(z), C₀(z), M+1 memory banks 30, 31, 32, M multipliers 33, 34 having each a variable gain G33, G34, and M adders 35, 36.

Each multiplier 33, 34 comprises an input, an output delivering a signal received on the input multiplied by the variable gain G33, G34, and a control input receiving the variable gain value.

Each adder 35, 36, comprises a first and a second inputs, and an output delivering the sum of the first and second inputs.

Each subfilter C_{M}(z), . . . , C₁(z), C₀(z) comprises an input 37, 38, 39 connected to the input 180 of the Farrow structure 18 and an output 40, 41, 42 connected to an input of a different memory bank 30, 31, 32.

An output of the M^{th} memory bank 30 is connected to the input of the M^{th} multiplier 33.

Each output of the M−1^{th} to the first memory banks 31, 32 is connected to the first input of a different adders 35, 36.

The output of the M^{th} multiplier is connected to the input of the next stage's adder. For example, as seen in FIG. 3, the output of multiplier 34 is connected to the second input of adder 36.

The output of the final adder 36 is connected to the output 181 of the Farrow structure 18.

Each memory bank 30, 31, 32 is connected to the control input 192 to select which memory data item of each memory bank 30, 31, 32 is forwarded to the multiplier G33, G34 and adders 35, 36.

The control input of the M variable gains G33, G34 is connected to the control input 182 of the Farrow structure 18 to control the value of the variable gains to be used with each memory data item, the value of each variable gain for a memory data item being identical and stored in the memory 100.

As the structure of the subfilters C_{M}(z), . . . , C₁(z), C₀(z) is identical, only the structure of the subfilters C_{M}(z) is detailed.

The subfilter C_{M}(z) comprises a chain of N delay elements 43, 44, N second multipliers 45, 46, 47, 48 and a second summer 49.

The N second multipliers 45, 46, 47, 48 multiply N+1 frequency bins xₙ of the second intermediary vector VI2 received on the input 37 of the subfilter C_{M}(z) by the N+1 filter coefficients C_{M0} to C_{MN} and deliver the multiplied sequential samples xₙ to the second summer 49.

The second summer 49 sums the N+1 sequential samples xₙ multiplied by the N+1 second multipliers 45, 46, 47, 48 and delivers the sum to the input of the memory bank 30.

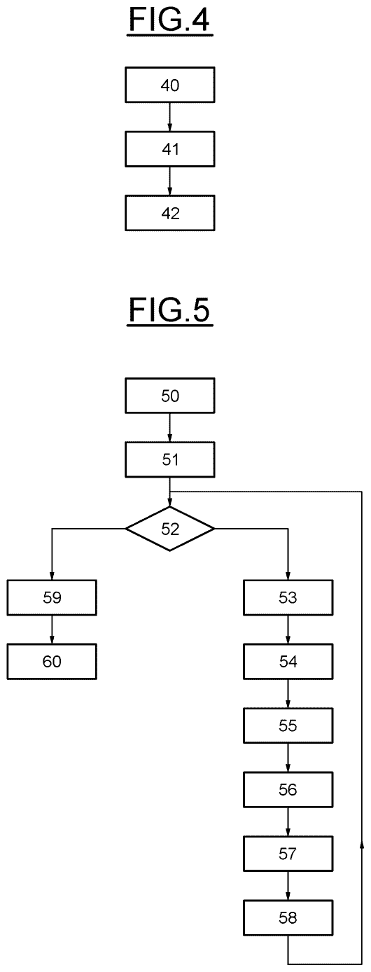

FIG. 4 illustrates an example of a known method from the prior art to determine the coefficients Cₘₙ of the coefficient matrix C of dimension (M+1)×(N+1).

In a step 40, the order N of the Farrow structure 18 and the order M of the polynomial is defined according to the required accuracy of the device 10.

At any single instant of time, the fractional values μ of the control value Δ of each multiplier G33, G34 is the same.

In another embodiment, the fractional values μ of the control value Δ of each multiplier G33, G34 may be varying on a sample by sample basis and are denoted μ1ₙ. The values of the fractional delay μ1ₙ are controlled by a control unit of the device 10 (not represented) and are chosen according to the needed fractional delay to be applied to each input sample xₙ. The control unit also selects which data sample is extracted from memory banks 30, 31, 32 according to the fractional delay μ1ₙ to achieve the necessary integer component of the needed delay.

To provide for the implementation of a continuous range of delays, the Farrow structure relies on a polynomial curve fitting based on a set of fixed-delay reference filters. For example, assuming a bank of eight reference filters each implementing a fixed delay, the fixed delay μ1 for each reference filter could be chosen between −0.5 to 0.5 in increments of 0.125 so that the integer j varies between 0 and 7 with μ1₀=−0.5, μ1₁=−0.375, . . . μ1₇=+0.375.

In a step 41, a set of functions gⱼ(n, μ1ⱼ) is computed for each j value and a given n value.

The function gⱼ may be for example equal to:

$${g}_{j} ( n , {μ1}_{j} ) = \frac{sin ( π ( n - μ {1}_{j} ) )}{π ( n - μ {1}_{j} )} \qquad ( 7 )$$

In step 42, the coefficients Cₘₙ of the coefficient matrix C are determined so that for a given n value and the desired delay value μ1, the filter coefficient h1(n, μ1) fits the polynomial interpolation of functions gⱼ(n, μ1ⱼ) defined by Cₘₙ for all values of u between −0.5 to +0.5.

FIG. 5 illustrates an example of a method for processing the digital signal S9 implementing the device 10.

It is assumed that the coefficient matrix C is defined and that the subfilters C_{M}(z), . . . , C₁(z), C₀(z) of the Farrow structure 18 is parametrized according to the coefficient matrix C.

In a step 50, the sampler 9 delivers the digital signal S9 comprising the samples xₚ from the continuous signal S8 delivered by the sensor 8.

The samples xₚ are stored in the memory 14.

In a step 51, the segmenting means 15 determine the frames F1, F2, . . . , Fₖ, Fₖ₊₁ and cluster the plurality of frames in a plurality of pairs of frames, each pair of frames comprising a first frame Fi and a second frame Fj, i, j being two different integers between 1 and P.

For each pair of frames comprising the first frame Fi and the second frame Fj (step 52), during a step 53, the spectral analysis means 16 perform a spectral analysis of the first frame Fi to determine the first vector V1 and a spectral analysis of the second frame Fj to determine the second vector V2.

During a step 54, the first determining means 17 determine the first intermediary unit vector VI1 and the second intermediary vector VI2.

During a step 55, the second determining means 20 determine a first array of speed change coefficients. Each speed change coefficient is representative of an expected speed change of the rotating element.

The speed change coefficients may be determined from a technical notice of the machine 1 or an operator of the machine 1.

The first array is for example stored in the memory 27.

During a step 56, the third determining means 21 determine a first initial value from the first array of speed change coefficients.

For each speed change coefficient of the first array, the third determining means 21 set a first control variable Δ1 to the value of the said speed change coefficient and deliver the first control variable Δ1 on the connection 182 of the Farrow structure 18.

The Farrow structure controlled by the first control variable Δ1 resamples the frequency bins of the second intermediary vector VI2 from an original unit index increment representative of the sampling of the continuous signal S8 at the fixed sample rate to a first index increment.

The second intermediary vector VI2 resampled at the first index increment and normalized is a first unit vector VR1 which is delivered on the output 181 of the Farrow structure 18.

The computation means 26 determine an inner product value IP of the first intermediary vector VI1 and the first unit vector VR1.

The inner product value IP and the first control variable Δ1 value are stored in a second array of the memory 27.

When the inner product value IP and the first control variable Δ1 value associated to each speed change coefficient of the first array are stored in the second array of the memory 27, the third determining means 21 determine the greatest inner product value of the plurality of inner product values stored in the second array and the associated first control variable value. The first control variable value associated to the greatest inner product value of the said plurality of inner product values is the first initial value.

During a step 57, the implementing means 24 determine the first control variable Δ1 and a second control variable Δ2.

The control variable Δ1 and the second control variable Δ2 are determined by the iterative line search method LSM to converge the difference between a first inner product value IP1 and a second inner product value IP2 toward zero.

The initial conditions of the iterative line search method LSM comprises at least the first initial value determined in step 56 and a second initial value bigger than the first initial value.

The first inner product value IP1 is determined from the inner product of the first intermediary unit vector VI1 and the first resulting unit vector VR1, and the second inner product value IP2 is determined from the inner product of the first intermediary unit vector VI1 and the second resulting unit vector VR2.

The Farrow structure 18 controlled by the first control variable Δ1 resamples the frequency bins of the second intermediary vector VI2 from the original unit index increment representative of the sampling increment of the continuous signal S8 at the fixed sample rate to the first index increment. The second intermediary vector VI2 resampled at the first index increment and normalized is the first resulting unit vector VR1.

Further, the Farrow structure 18 controlled by the second control variable Δ2 resamples the frequency bins of the second intermediary vector VI2 from the original unit index increment to a second index increment. The second intermediary vector VI2 resampled at the second index increment and normalized is the second resulting unit vector VR2.

During a step 57, the fourth determining means 22 determine a result value Bp when the difference between the first inner product value IP1 and the second inner product value IP2 is smaller than a predetermined threshold or the number of iterations of the iterative line search method LSM is equal to a predetermined number of iterations.

The number of iterations of the iterative line search method LSM implemented by the implementing means 24 is determined by the counter 25.

The result value is equal to the means of the first and second control variables Δ1, Δ2.

The fourth determining means 22 further store the result value Bp in a result array of the memory 27 and a timestamp value tₚ determined from the sequential samples of the said pair of frames Fi, Fj.

When the result value of each pair of the plurality of pairs of frames Fi, Fj is stored in the result array (step 52), the method continues in step 59.

The result array comprises result values Bp and associated timestamp value tₚ, p being between 1 and P, P being the number of frames.

During the step 59, the fifth determining means 23 determine a correction profile from the result values and timestamp values stored in the result array.

For each result value, the fifth determining means 23 determine a result timestamp value from the timestamp values associated to the said result value, obtain arrays of the result values depending on their result timestamp values, and apply an interpolation to the result values to obtain the correction profile.

The interpolation may be a linear or spline interpolation of the Bp result values stored in the result array to obtain the correction profile.

During a step 60, the fifth determining means 23 determine a third control variable Δ3 following the correction profile determined at step 59 and deliver the third control variable Δ3 to the connection 182 of the Farrow structure 18.

The Farrow structure 18 resamples sequential timestamped samples xₚ of the continuous signal S8 stored in the memory 14.

The Farrow structure 18 delivers the resampled sequential timestamped samples xₚ of the continuous signal S8 at the output 102 of the device 10.

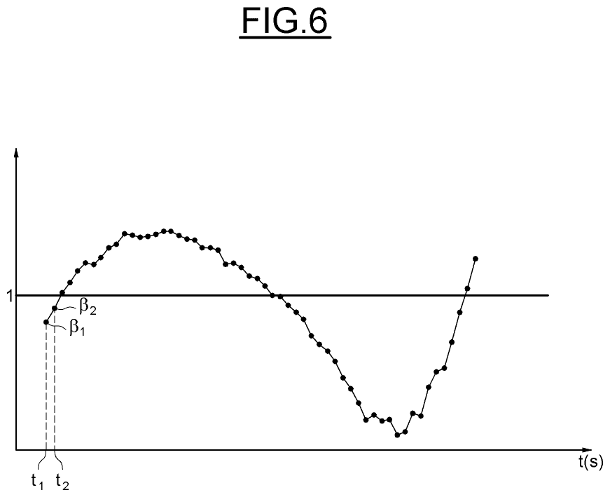

FIG. 6 illustrates an example of correction profile comprising result values β₁, β₂, . . . βₚ and associated timestamp value t₁, t₂, . . . tₚ.

When Bp is smaller than 1, the speed of the rolling bearing 4 is decreasing, when βₚ is bigger than 1, the speed of the rolling bearing 4 is increasing and when βₚ is equal to 1, the speed of the rolling bearing 4 is constant.

The output signal Sout is delivered on the output 102 of the device 10.

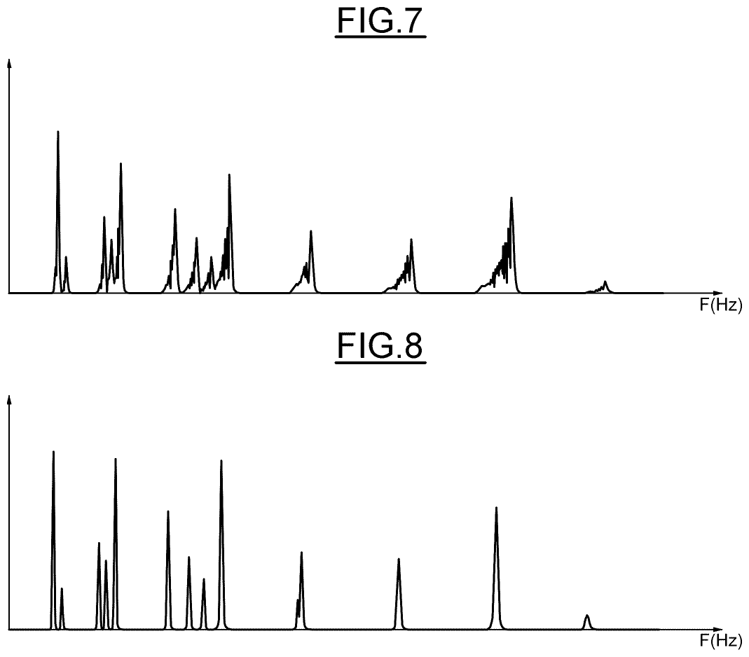

FIG. 7 illustrates an example of the spectrum of vibrations delivered by the sensor 8 without speed compensation and FIG. 8 illustrates the spectrum of vibrations delivered by the sensor 8 delivered by the second implementing means 12 (with speed compensation).

The tones are easily identifiable on the spectrum of vibrations of FIG. 8, whereas on the spectrum of vibrations of FIG. 7, the tones are smeared.

The device 10 allows machine-health assessment for systems and/or sensors which have no means for direct rotational speed measurement.

The device 10 allows to use of any existing algorithm that has been designed for constant speed conditions and are industrially accepted, trusted and well-understood.

The device 10 further obviates repetitive attempts at data acquisition that only must be discarded due to speed changes.

Instead, such data may now be used effectively. The suppression of repetitive attempts at data acquisition permit to save supply power of a system comprising the sensor 8, the sampler 9 and the device 10, for example a wireless system comprising a supply source such as a battery.

The iterative line search method LSM may be a golden section line search method known from the prior art or a parabolic line search method or Successive Parabolic Interpolation.

The initial conditions of the iterative parabolic line search further comprising a third initial value equal to the means value of the first and second initial values.

What is claimed is:

1. A method for processing a continuous signal sampled at a fixed sample rate, the continuous signal being representative of the operation of a rotating element, the rotating element undergoing rotational speed changes, the method comprising:
segmenting the sequential timestamped samples of the digital signal into a plurality of frames and clustering the plurality of frames in a plurality of pairs of frames, each pair of frames comprising a first frame and a second frame so that samples of the second frame are sampled after the samples of the first frame;
for each pair of frames:
(a) performing a spectral analysis of the first frame to determine a first vector comprising frequency bins below or equal to the Nyquist frequency of the sampling of the continuous signal;
(b) performing a spectral analysis of the second frame to determine a second vector comprising frequency bins below or equal to the Nyquist frequency of the sampling of the continuous signal;
(c) determining a first intermediary unit vector comprising the absolute value of at least one frequency bin of the first vector and a second intermediary vector comprising the absolute value of at least one frequency bin of the second vector;
(d) determining a first array of speed change coefficients, each speed change coefficient being representative of an expected speed change of the rotating element;
(e) determining a first initial value from the first array of speed change coefficients;
(f) resampling the frequency bins of the second intermediary vector by a Farrow structure controlled by a first control variable from an original unit index increment representative of the sampling increment of the continuous signal at the fixed sample rate to a first index increment, the second intermediary vector resampled at the first index increment and normalized being a first resulting unit vector, and resampling the frequency bins of the second intermediary vector by the Farrow structure controlled by a second control variable from the original unit index to a second index increment, the second intermediary vector resampled at the second index increment and normalized being a second resulting unit vector, the first and second control variable being determined by an iterative line search method to converge the difference between a first inner product value and a second inner product value toward zero, the initial conditions of the iterative line search method comprising at least the first initial value and a second initial value bigger than the first initial value, the first inner product value being determined from the inner product of the first intermediary unit vector and the first resulting unit vector, and the second inner product value being determined from the inner product of the first intermediary unit vector and the second resulting unit vector;
(g) determining a result value when the difference between the first inner product value and the second inner product value is smaller than a predetermined threshold or the number of iterations of the iterative line search method is equal to a predetermined number of iterations, the result value being equal to the means of the first and second control variables, and storing the result value in a result array and a timestamp value determined from the sequential samples of the said pair of frames;
when the result value of each pair of the plurality of pairs of frames is stored in the result array, determining a correction profile from the result values and timestamp values stored in the result array; and
resampling the sequential timestamped samples of the continuous signal by the Farrow structure controlled by a third control variable, the third control variable following the correction profile; and
delivering the resampled sequential timestamped samples of the continuous signal.

2. The method according to claim 1, wherein determining the first initial value comprises for each speed change coefficient of the first array:
setting the first control variable to the value of the said speed change coefficient;
resampling the frequency bins of the second intermediary vector by the Farrow structure controlled by the first control variable from an original unit index increment representative of the sampling of the continuous signal at the fixed sample rate to a first index increment, the second intermediary vector resampled at the first index increment and normalized being a first unit vector;
determining the inner product value of the first intermediary vector and the first unit vector, and storing the inner product value and the first control variable value in a second array; and
determining the greatest inner product value of the plurality of inner product values stored in the second array and the associated first control variable value, the associated first control variable value being the first initial value.

3. The method according to claim 1, wherein determining the correction profile comprises:
for each result value, determining a result timestamp value from the timestamp values associated to the said result value;
obtaining arrays of the result values depending on their result timestamp values; and
applying an interpolation to the result values to obtain the correction profile.

4. The method according to claim 1, wherein the iterative line search method comprises a golden section line search.

5. The method according to claim 1, wherein the iterative line search method comprises a parabolic approximation line search, the initial conditions of the iterative line search method further comprising a third initial value equal to the means value of the first and second initial values.

6. The method according to claim 1, further comprising zero padding of at least the first and second frames before performing the spectral analysis.

7. The method according to claim 2, wherein determining the correction profile comprises:
for each result value, determining a result timestamp value from the timestamp values associated to the said result value;
obtaining arrays of the result values depending on their result timestamp values; and
applying an interpolation to the result values to obtain the correction profile.

8. The method according to claim 7, wherein the iterative line search method comprises a golden section line search.

9. The method according to claim 7, wherein the iterative line search method comprises a parabolic approximation line search, the initial conditions of the iterative line search method further comprising a third initial value equal to the means value of the first and second initial values.

10. The method according to claim 9, further comprising zero padding of at least the first and second frames before performing the spectral analysis.

11. A device for processing a digital signal comprising sequential samples of a continuous signal sampled at a fixed sample rate, the continuous signal being representative of the operation of a rotating element, the rotating element undergoing rotational speed changes, the device comprising:
segmenting means configured to segment the sequential timestamped samples of the digital signal into a plurality of frames and to cluster the plurality of frames in a plurality of pairs of frames, each pair of frames comprising a first frame and a second frame so that samples of the second frame are sampled after the samples of the first frame;
spectral analysis means configured to perform a spectral analysis of the first frame to determine a first vector comprising frequency bins below or equal to the Nyquist frequency of the sampling of the continuous signal and a spectral analysis of the second frame to determine a second vector comprising frequency bins below or equal to the Nyquist frequency of the sampling of the continuous signal;
first determining means configured to determine a first intermediary unit vector comprising the absolute value of at least one frequency bin of the first vector and a second intermediary vector comprising the absolute value of at least one frequency bin of the second vector;
second determining means configured to determining a first array of speed change coefficients, each speed change coefficient being representative of an expected speed change of the rotating element;
third determining means configured to determine a first initial value from the first array of speed change coefficients;
a Farrow structure configured to:
be controlled by a first control variable to resample the frequency bins of the second intermediary vector from an original unit index increment representation of the sampling increment of the continuous signal at the fixed sample rate to a first index), the second intermediary vector resampled at the first index increment and normalized being a first resulting unit vector;
be controlled by a second control variable to resample the frequency bins of the second intermediary vector from the original unit index to a second index increment, the second intermediary vector resampled at the second index increment and normalized being a second resulting unit vector; and
be controlled by a third control variable to resample the sequential timestamped samples of the continuous signal, the third control variable following a correction profile;
implementing means configured to implement an iterative line search method to determine the first and second control variable by converging the difference between a first inner product value and a second inner product value toward zero, the initial conditions of the iterative line search method comprising at least the first initial value and a second initial value bigger than the first initial value, the first inner product value being determined from the inner product of the first intermediary unit vector and the first resulting unit vector, and the second inner product value being determined from the inner product of the first intermediary unit vector and the second resulting unit vector;
fourth determining means configured to determine a result value when the difference between the first inner product value and the second inner product value is smaller than a predetermined threshold or the number of iterations of the iterative line search method is equal to a predetermined number of iterations, the result value being equal to the means of the first and second control variables, and configured to store the result value in a result array and a timestamp value determined from the sequential samples of the said pair of frames;
fifth determining means configured to determine the correction profile from the result values and timestamp values stored in the result array when the result value of each pair of the plurality of pairs of frames is stored in the result array.

12. A bearing device comprising:
a bearing having an inner ring and an outer ring rotatable concentrically relative to one another;
a sensor configured to measure vibrations of said inner ring or outer ring, the sensor configured to deliver a continuous signal;
a sampler configured to sample the continuous signal at a fixed sample rate, the sampler configured to deliver a digital signal comprising the sequential samples; and
the device according to claim 11 configured to process the digital signal.
